(19) United States
(12) Patent Application Publication
(10) Pub. No.: US 2006/0283833 A1
(43) Pub. Date: Dec. 21, 2006

(54) Wiring for display device and thin film transistor array panel with the same, and manufacturing method thereof

(75) Inventors: Je-Hun Lee, Seoul (KR); Sung-Hoon Yang, Seoul (KR); Chang-Oh Jeong, Suwon-si (KR); Beom-Seok Cho, Seoul (KR); Yang-Ho Bae, Suwon-si (KR)

Correspondence Address: MACPHERSON KWOK CHEN & HEID LLP, 2033 GATEWAY PLACE, SUITE 400, SAN JOSE, CA, 95110, US

(73) Assignee: Samsung Electronics Co., Ltd.

(21) Appl. No.: 11/374,938

(22) Filed: Mar. 13, 2006

(30) Foreign Application Priority Data
Jun. 15, 2005 (KR) 10-2005-0051241

(51) Int. Cl. C30B 33/00; B44C 1/22; G02F 1/1343

(52) U.S. Cl. 216/23; 216/83; 349/139

(57) ABSTRACT

A TFT array panel for an LCD includes a substrate, a first signal line and a second signal line that cross each other on the substrate, a TFT that is connected to the first signal line and the second signal line, and a pixel electrode that is connected to the TFT. Here, at least one of the two signal lines includes a first conductive layer containing molybdenum, a second conductive layer that is formed on the first conductive layer and contains copper, and a third conductive layer that is formed on the second conductive layer and contains a conductive oxide.

### CROSS-REFERENCE TO RELATED APPLICATIONS

This application claims priority to Korean Patent Application No. 10-2005-0051241, filed in the Korean Patent Office on Jun. 15, 2005, the disclosure of which is hereby incorporated by reference in its entirety.

### BACKGROUND

(a) Field of the Invention

The present invention relates to a thin film transistor array panel and a method of manufacturing the same.

(b) Description of the Related Art

In recent years, liquid crystal displays (LCDs) have been the most widely used flat panel display device.

Generally, an LCD includes a pair of panels having pixel electrodes and a common electrode on their inner surfaces, and a dielectric anisotropic LC layer interposed between the panels. In the LCD, the pixel electrodes supplied with voltages generate electric fields in cooperation with the common electrode supplied with a voltage, thereby determining the orientations of LC molecules in the LC layer interposed between the two electrodes. The transmittance of light passing through the LC layer is varied depending on the orientations of the LC molecules.

In general, the pixel electrodes and the common electrode are formed on different substrates. In this case, the pixel electrodes are arranged in a matrix on a lower substrate, while the common electrode is formed to completely cover an upper substrate. The lower substrate has as many TFTs as the number of the pixel electrodes, and display signal lines consisting of gate signals and data lines.

The TFTs, connected to the pixel electrodes, serve as switching elements that intercept image signals, which are applied through the data lines in response to scanning signals applied through the gate lines, or transmit image signals to the pixel electrodes. Similarly, in active matrix organic light-emitting diode displays (AMOLEDs), the TFTs serve as the switching elements for controlling light-emitting diodes.

Meanwhile, as screens of display devices such as LCDs, OLEDs, etc., become larger, the display signal lines, which are connected to the respective TFTs, become longer and resistance of the display signal lines also increases. Some problems may occur, such as signal delay and voltage drop, because of the increased resistance of the display signal lines. To solve the problems, it is desirable to use low resistivity metallic materials for the formation of the display signal lines.

Copper (Cu), a representative low resistivity metal, is a material suitable for solving such problems. However, when the display signal lines are made of only Cu, the wiring is apt to peel off from the substrate, since Cu provides poor adhesion with the substrate. In addition, if the Cu wiring is directly exposed to chemical materials, such as an etchant, etc., the exposed portions are stained and resistance of those portions increases.

Further, Cu easily diffuses into other layers that are in contact with the Cu wiring due to the oxidation property of Cu, thus degrading the characteristics of the TFTs.

### SUMMARY

In accordance with embodiments of the present invention, improved adhesion between a substrate and Cu wiring having low resistivity and prevention of diffusion of Cu into other layers are provided.

In accordance with an aspect of the present invention, there is provided a lead for a display device including a first conductive layer comprising molybdenum (Mo), a second conductive layer formed on the first conductive layer and comprising copper (Cu), and a third conductive layer formed on the second conductive layer and comprising a conductive oxide.

According to another aspect of the present invention, there is provided a TFT array panel including a substrate, a first signal line and a second signal line that cross each other on the substrate, a TFT that is connected to the first signal line and the second signal line, and a pixel electrode that is connected to the TFT.

In this structure, at least one of the two signal lines includes a first conductive layer comprising Mo, a second conductive layer that is formed on the first conductive layer and comprising copper (Cu), and a third conductive layer that is formed on the second conductive layer and comprising a conductive oxide.

According to still another aspect of the present invention, there is provided a manufacturing method of a TFT array panel including the steps of forming a first signal line, forming a gate insulating layer and a semiconductor layer on the first signal line, forming a second signal line and a drain electrode on the gate insulating layer and the semiconductor layer, and forming a pixel electrode that is connected to the drain electrode.

Here, at least one of the formation steps of the first signal line and the second signal line includes the sub-steps of forming a first conductive layer comprising Mo, forming a second conductive layer comprising Cu, and forming a third conductive layer comprising a conductive oxide.

### BRIEF DESCRIPTION OF THE DRAWINGS

The present invention will become more apparent by describing the preferred embodiments thereof in more detail with reference to the accompanying drawings.

FIG. 1 is a layout view of a TFT array panel according to an embodiment of the present invention.

FIG. 2 is a cross-sectional view cut along II-II′ of FIG. 1.

FIG. 3 is a cross-sectional view cut along III-III′ of FIG. 1.

FIG. 4, FIG. 7, FIG. 10, and FIG. 13 are layout views showing process steps for manufacturing a TFT array panel according to an embodiment of the present invention.

FIG. 5 and FIG. 6 are schematic cross-sectional views cut along V-V′ and VI-VI′ of FIG. 4.

FIG. 8 and FIG. 9 are schematic cross-sectional views cut along VIII-VIII′ and IX-IX′ of FIG. 7.

FIG. 11 and FIG. 12 are schematic cross-sectional views cut along XI-XI′ and XII-XII′ of FIG. 10.

FIG. 14 and FIG. 15 are schematic cross-sectional views cut along XIV-XIV′ and XV-XV′ of FIG. 13.

### DETAILED DESCRIPTION OF THE PREFERRED EMBODIMENTS

Preferred embodiments of the present invention will now be described more fully hereinafter with reference to the accompanying drawings, in which preferred embodiments of the invention are shown. The present invention may, however, be embodied in different forms and should not be construed as being limited to the embodiments set forth herein. Rather, these embodiments are provided so that this disclosure will be thorough and complete, and will fully convey the scope of the invention to those skilled in the art.

In the drawings, the thickness of the layers, films, and regions may be exaggerated for clarity. Like numerals refer to like elements throughout. It will be understood that when an element such as a layer, film, region, or substrate is referred to as being “on” another element, it can be directly on the other element or intervening elements may also be present.

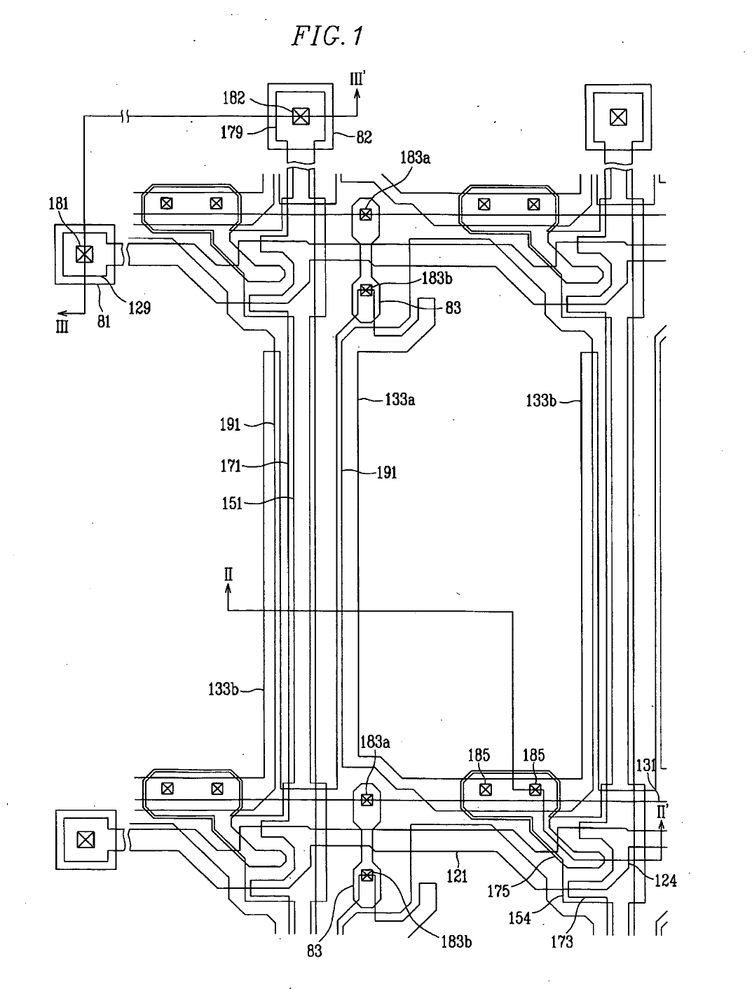

Hereinafter, a TFT array panel according to an embodiment of the present invention will be described in detail with reference to FIG. 1 through FIG. 3.

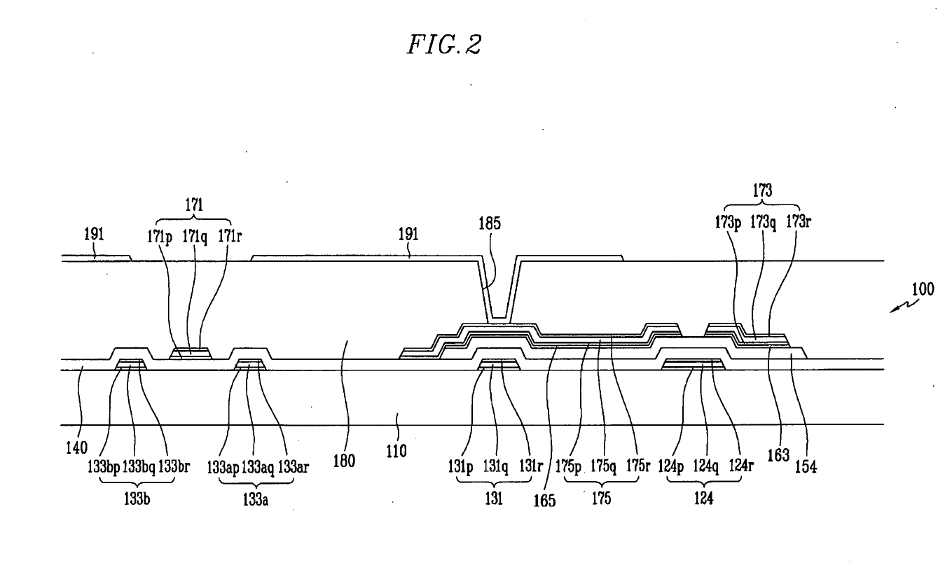

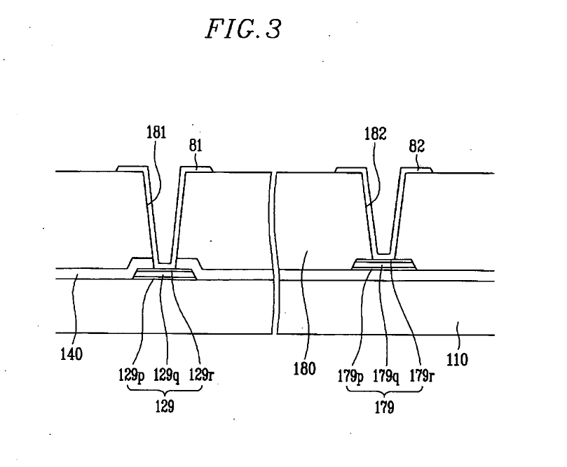

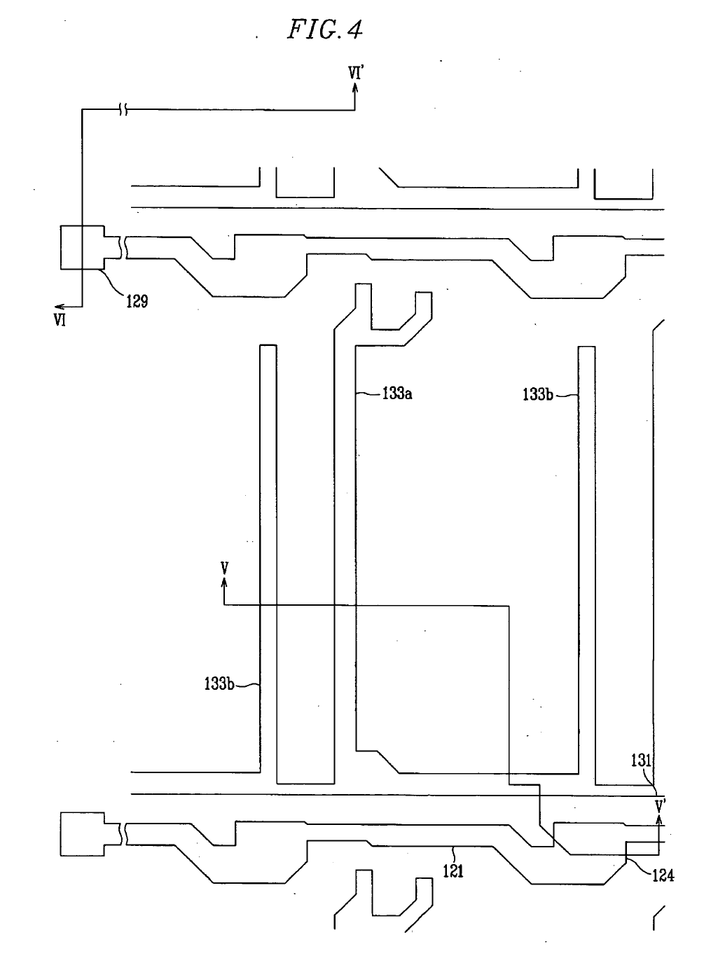

FIG. 1 is a layout view of a TFT array panel according to an embodiment of the present invention, and FIG. 2 and FIG. 3 are cross-sectional views cut along II-II′ and III-III′ of FIG. 1, respectively.

A plurality of gate lines 121 and a plurality of storage electrode lines 131 are formed on an insulating substrate 110 made of transparent glass or plastic.

The gate lines 121 for transmitting gate signals extend substantially in a horizontal direction. Each gate line 121 includes a plurality of gate electrodes 124 protruding downward and an end portion 129 having a relatively large dimension to be connected for connection to a different layer or an external device. Gate drivers (not shown) for generating the gate signals may be mounted on a flexible printed circuit film (not shown) attached to the substrate 110, or directly on the substrate 110. Otherwise, the gate drivers may be integrated into the substrate 110. In this case, the gate lines 121 are directly connected to the gate drivers.

The storage electrode lines 131 receive a predetermined voltage. Each storage electrode line 131 includes a stem line that is substantially parallel to the gate lines 121, and a plurality of pairs of storage electrodes 133a and 133b that extend from the stem line substantially in a vertical direction. Each storage electrode line 131 is placed between two adjacent gate lines 121. In this embodiment, the stem line of the storage electrode line 131 is closer to the lower-positioned gate line. Each storage electrode 133a has a fixed end, connected to one of the stem lines, and a free end. Each storage electrode 133b has a fixed end with a relatively large dimension, which is connected to one of the stem lines, and two free ends including a straight free end and a crooked free end. However, the form and arrangement of the storage electrode lines 131 may be varied in other embodiments.

Referring to FIG. 2 and FIG. 3, the gate lines 121 and the storage electrode lines 131 are configured as triple-layered structures. Lower layers 124p, 129p, 131 p, 133ap, and 133bp are made of Mo or a Mo alloy that contains Mo as a base metal and at least one among niobium (Nb), tantalum (Ta), titanium (Ti), zirconium (Zr), tungsten (W), and nitride (N). Intermediate layers 124q, 129q, 131q, 133aq, and 133bq are made of Cu ora Cu alloy. Upper layers 124r, 129r, 131r, 133ar, and 133br are made of a conductive oxide such as indium tin oxide (ITO), indium zinc oxide (IZO), aluminum zinc oxide (AZO), or indium tin zinc oxide (InSnZnO). Hereinafter, the lower layers 124p, 129p, 131p, 133ap, and 133bp will be referred to as Mo layers, the intermediate layers 124q, 129q, 131q, 133aq, and 133bq as Cu layers, and the upper layers 124r, 129r, 131r, 133ar, and 133br as conductive oxide layers, even though other materials may be present in the various layers.

The Mo layers 124p, 129p, 131p, 133ap, and 133bp, and the conductive oxide layers 124r, 129r, 131r, 133ar, and 133br, which are formed under and on the Cu layers 124q, 129q, 131q, 133aq, and 133bq, respectively, provide improved adhesion between the Cu layers and the underlying substrate 110 and between the Cu layers and overlying layers.

Also, when the above-mentioned three layers form a triple-layered stack, the stack can achieve a good etching profile for a single etchant. This will be described below in more detail.

The Mo layer and the Cu layer ordinarily have different etching ratios when using the same etchant. When forming a stack of layers, however, the layers can achieve a desirable profile as a result of the galvanic effect. The galvanic effect is an phenomenon in which when a potential difference exists between two dissimilar metals that are electrically connected in an electrolyte, one of the metals, which is positively charged, becomes a cathode at which reduction occurs, while the other, which is negatively charged, becomes an anode at which oxidation occurs. In this case, the metal serving as the anode corrodes faster than it would by itself, while the metal serving as the cathode corrodes slower that it would alone. The galvanic effect depends on the thickness ratio between the cathode and anode, and therefore the etching ratio between the two metals can be controlled according to the thickness of the two.

For instance, for an etchant containing hydrogen peroxide (H₂O₂), the Cu layer is more rapidly etched than the Mo layer. However, in the case when the two layers form a stack, the Cu layer acts as a cathode and thus corrodes more rapidly than it would alone, while the Mo layer acts as an anode and thus corrodes more slowly than it would alone. Accordingly, the stack, including the underlying Mo layer and overlying Cu layer, can achieve a good etching profile.

The conductive oxide layers, which are formed on the Cu layers, are made of ITO, IZO, AZO, InSnZnO, or the like. The conductive oxide layers prevent Cu from diffusing into the overlying layers.

The conductive oxide layers have a significantly lower etching ratio as compared to the Cu layer. However, when the two layers form a stack, the stack can achieve a good etching profile using the same etchant since the conductive oxide layer is more greatly exposed to the etchant than the Cu layer and is formed more thinly than the Cu layer. Also, the conductive oxide layer provides a prominent ohmic contact property with the Cu layer. Accordingly, the conductive oxide layer can prevent wiring from peeling off from the underlying substrate.

In addition, the conductive oxide layer may be made of a nitride-containing conductive oxide such as ITON, IZON, AZON, InSnZnON, or the like. In this case, such materials restrain oxidation of Cu at a contact region between the Cu layer and the conductive oxide layer, thus preventing resistance from rapidly increasing.

The thickness of the Mo layers 124p, 129p, 131 p, 133ap, and 133bp, the Cu layers 124q, 129q, 131q, 133aq, and 133bq, and the conductive oxide layers 124r, 129r, 131r, 133ar, and 133br can be individually controlled depending on etching properties of the formation material of each layer. Preferably, the Mo layers 124p, 129p, 131 p, 133ap, and 133bp, and the conductive oxide layers 124r, 129r, 131r, 133ar, and 133br, have a thickness of 0 Å to 1000 Å, and the Cu layers 124q, 129q, 131q, 133aq, and 133bq, have a thickness of 100 Å to 2 μm.

All lateral sides of the gate lines 121 and the storage electrode lines 131 preferably slope in the range from about 30° to 80° relative to the surface of the substrate 110.

A gate insulating layer 140 made of silicon nitride (SiNₓ) or silicon oxide (SiO₂) is formed on the gate lines 121 and the storage electrode lines 131.

A plurality of linear semiconductors 151 made of hydrogenated amorphous silicon (abbreviated as “a-Si”) or polysilicon are formed on the gate insulating layer 140. Each linear semiconductor 151 extends substantially in a vertical direction, including a plurality of projections 154 that extend along the respective gate electrodes 124. The linear semiconductors 151 are enlarged in the vicinities of the gate lines 121 and the storage electrode lines 131 to cover them widely.

A plurality of linear ohmic contacts 161 and island-shaped ohmic contacts 165 are formed on the linear semiconductors 151. The ohmic contacts 161 and 165 may be made of N+ hydrogenated amorphous silicon that is highly doped with N-type impurities such as phosphorus (P), or silicide. The linear ohmic contacts 161 include a plurality of projections 163. A set of a projection 163 and an island-shaped ohmic contact 165 are placed on the projection 154 of the semiconductor 151.

All lateral sides of the linear semiconductors 151 and the ohmic contacts 161 and 165 preferably slope in the range from about 300 to 800 relative to the surface of the substrate 110.

A plurality of data lines 171 and a plurality of drain electrodes 175 are formed on the ohmic contacts 161 and 165 and the gate insulating layer 140.

The data lines 171 for transmitting data signals extend substantially in a vertical direction to be crossed with the gate lines 121 and the stem lines of the storage electrode lines 131. In this embodiment, each pair of the storage electrodes 133a and 133b is placed between two adjacent data lines 171. Each data line 171 includes a plurality of source electrodes 173 extending toward the respective gate electrodes 124, and an end portion 179 having a relatively large dimension to be connected to a different layer or an external device. Data drivers (not shown) for generating the data signals may be mounted on a flexible printed circuit film (not shown) attached to the substrate 110, or directly on the substrate 110. Otherwise, the data drivers may be integrated into the substrate 110. In this case, the data lines 171 are directly connected to the gate drivers.

The drain electrodes 175 separated from the data lines 171 are opposite to the source electrodes 173, centering on the gate electrodes 124. Each drain electrode 175 includes an expansion having a relatively large dimension and a bar-shaped end portion. Each expansion overlaps with the stem line of the storage electrode line 131, and each bar-shaped end portion is partially surrounded by the curved source electrode 173.

A gate electrode 124, a source electrode 173, a drain electrode 175, and a projection 154 of the semiconductor 151 form a thin film transistor (TFT). A TFT channel is formed in the projection 154 provided between the source electrode 173 and the drain electrode 175.

The data lines 171 and the drain electrode 175 are configured as triple-layered structures. Lower layers 171p, 173p, 175p, and 179p are made of Mo or a Mo alloy that contains Mo as a base metal and at least one among Nb, Ta, Ti, Zr, W, and N. Intermediate layers 171q, 173q, 175q, and 179q are made of Cu or a Cu alloy. Upper layers 171r, 173r, 175r, and 179r are made of a conductive oxide such as ITO, IZO, AZO, or InSnZnO. Hereinafter, the lower layers 171p, 173p, 175p, and 179p will be referred to as Mo layers, the intermediate layers 171q, 173q, 175q, and 179q as Cu layers, and the upper layers 171r, 173r, 175r, and 179r as conductive oxide layers.

The Mo layers 171p, 173p, 175p, and 179p, and the conductive oxide layers 171p, 173p, 175p, and 179p are formed under and on the Cu layers 171q, 173q, 175q, and 179q, respectively, to prevent the Cu layers from diffusing into the substrate 110 and pixel electrodes 191.

The Mo layers 171p, 173p, 175p, and 179p enhance adhesion between the Cu layers 171q, 173q, 175q, and 179q and the underlying substrate 110, and provide prominent ohmic contact properties with the semiconductors.

Also, even when the Mo layers and the Cu layers are simultaneously etched with the same etchant, they can achieve desirable etching profiles.

The conductive oxides, such as ITO, IZO, AZO, InSnZnO, and the like, which are used for the formation of the conductive oxide layers 171r, 173r, 175r, and 179r, have prominent adhesion with Cu, while showing significantly low etching ratios compared to Cu. Accordingly, in this invention, the conductive oxide layers 171r, 173r, 175r, and 179r are configured to be more widely exposed to the etchant than the Cu layers 171q, 173q, 175q, and 179q and to be thinner than the Cu layers 171q, 173q, 175q, and 179q, in order to solve a problem caused by the difference of the etching ratio between the two layers.

The conductive oxide layers 171r, 173r, 175r, and 179r may be made of a nitride-containing conductive oxide such as ITON, IZON, AZON, InSnZnON, or the like. These materials prevent the Cu layers 171q, 173q, 175q, and 179q from being oxidized at contact regions between the Cu layers and the conductive oxide layers, thus preventing the resistance from rapidly increasing.

All lateral sides of the data lines 171 and the drain electrodes 175 preferably slope in the range from about 300 to 80° relative to the surface of the substrate 110.

The ohmic contacts 161 and 165 are provided only between the underlying semiconductors 151 and the overlying data lines 171 and between the overlying drain electrodes 175 and the underlying semiconductors 151, in order to reduce the contact resistance therebetween. Most of the linear semiconductors 151 are formed more narrowly than the data lines 171, but partial portions thereof may be enlarged in the vicinities of the regions crossing the gate lines 121 or the storage electrode lines 131, as previously mentioned, in order to prevent the data lines 171 from being shorted. The linear semiconductors 151 are partially exposed at places where the data lines 171 and the drain electrodes 175 do not cover them, as well as between the source electrodes 173 and the drain electrodes 175.

A passivation layer 180 is formed on the data lines 171, the drain electrodes 175, and the exposed portions of the semiconductors 151. The passivation layer 180 may be configured as a single layer made of an inorganic insulator, such as SiNₓ or SiO₂, an organic insulator, or a low dielectric insulator. A desirable dielectric constant of the organic insulator and the low dielectric insulator is below 4.0, and the low dielectric insulator can be selected from a-Si:C:O, a-Si:O:F, etc., which are produced by plasma enhanced chemical vapor deposition (PECVD). The organic insulator may have photosensitivity. A top surface of the passivation layer 180 may be planarized. The passivation layer 180 may also be configured as a double-layered structure including a lower inorganic insulator layer and an upper organic insulator layer. This structure maintains the prominent insulating property of the organic layer, preventing damage to the exposed portions of the semiconductors 151.

The passivation layer 180 is provided with a plurality of contact holes 182 and 185, through which the end portions 179 of the data lines 171 and the expansions of the drain electrodes 175 are exposed, respectively. A plurality of contact holes 181 are formed in the passivation layer 180 and the gate insulating layer 140, and the end portions 129 of the gate lines 121 are exposed therethrough. A plurality of pairs of contact holes 183a and 183b are also formed in the passivation layer 180 and the gate insulating layer 140, and the stem lines of the storage electrode lines 131, which are adjacent to the fixed ends of the storage electrodes 133a, and the straight free ends of the storage electrodes 133a are individually exposed therethrough.

A plurality of pixel electrodes 191, a plurality of overpasses 83, and a plurality of contact assistants 81 and 82 are formed on the passivation layer 180. These structures may be made of a transparent conductor, such as ITO or IZO, or a reflective metal, such as Al, Ag, Cr, or their alloys.

The pixel electrodes 191 are physically and electrically connected to the drain electrodes 175 through the contact holes 185 in order to receive data voltages from the drain electrodes 175. The pixel electrodes 191 supplied with the data voltages generate electric fields in cooperation with a common electrode (not shown) of another panel (not shown) facing the TFT array panel 100, thereby determining the orientations of LC molecules in the LC layer 3 interposed between the two electrodes. According to the orientations of the LC molecules, the polarization of light passing through the LC layer 3 is varied. Each set of the pixel electrode 191 and the common electrode forms an LC capacitor that is capable of storing the applied voltage after the TFT is turned off.

The pixel electrodes 191 partially overlap with the storage electrodes 133a and 133b as well as the stem lines of the storage electrodes 131. To enhance the voltage storage ability of the LC capacitors, storage capacitors are further provided. The storage capacitors are implemented by overlapping the pixel electrodes 191 and the drain electrodes 175, that are electrically connected thereto, with the storage electrode lines 131.

The contact assistants 81 and 82 are connected to the end portions 129 of the gate lines 121 and the end portions 179 of the data lines 171 through the contact holes 181 and 182, respectively. The contact assistants 81 and 82 supplement adhesion between the exposed end portions 129 and 179 and exterior devices, and protect them.

The overpasses 83 span the gate lines 121. Each pair of the overpasses 83, adjacent to each other upward and downward, are individually connected to the exposed stem line of the storage electrode line 131 and the exposed straight free end of the storage electrode 133a through the contact holes 183a and 183b. The overpasses 83 and the storage electrode lines 131 having the storage electrodes 133a and 133b may be used for repairing defects in the gate lines 121 and/or the data lines 171.

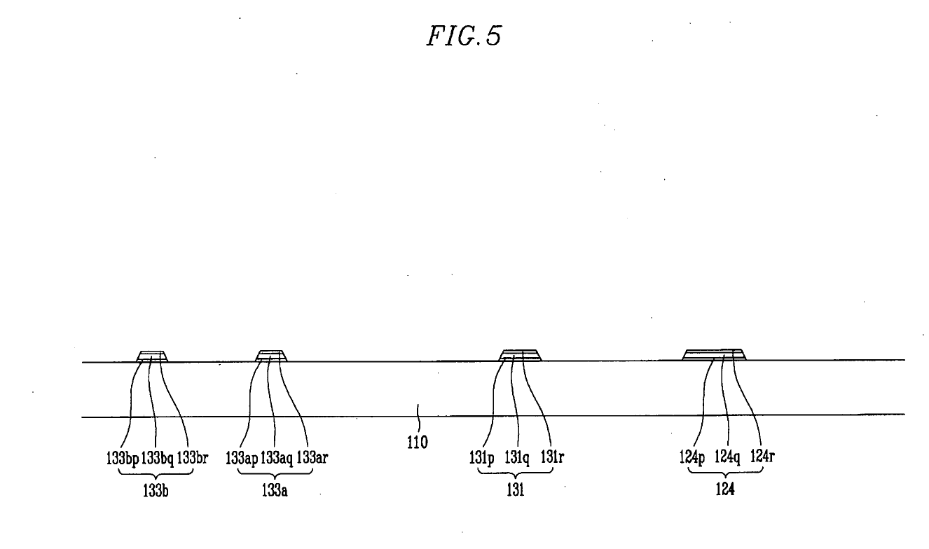

Hereinafter, a manufacturing method of the TFT array panel 100 shown in FIG. 1 through FIG. 3 will be described in detail with reference to FIG. 4 through FIG. 15.

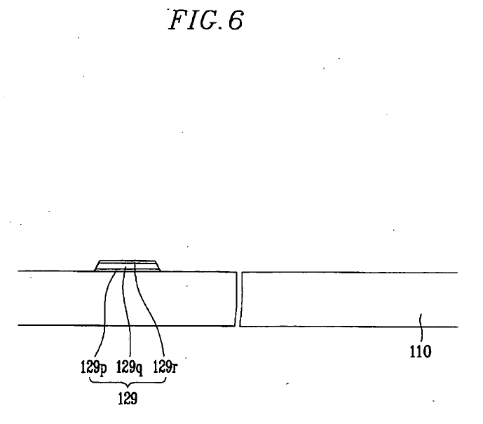

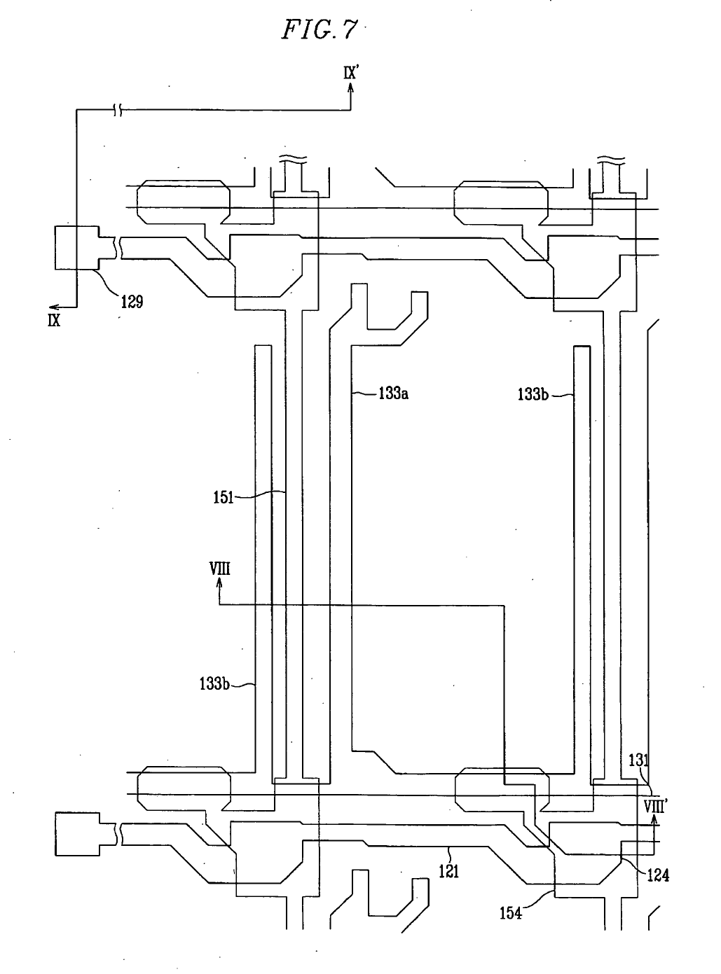

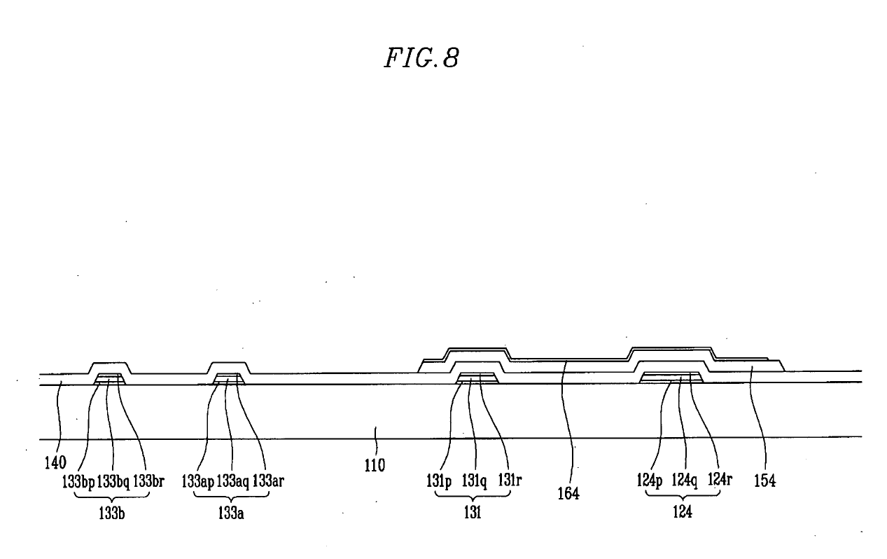

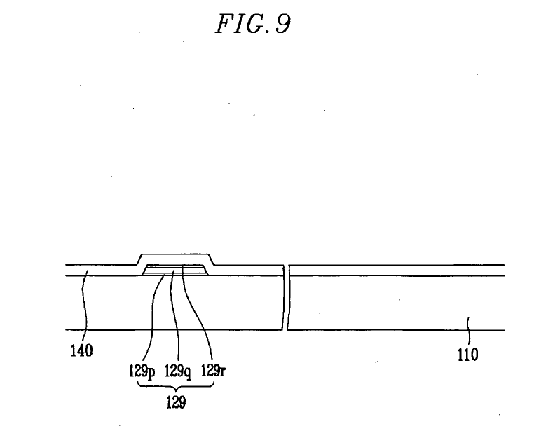

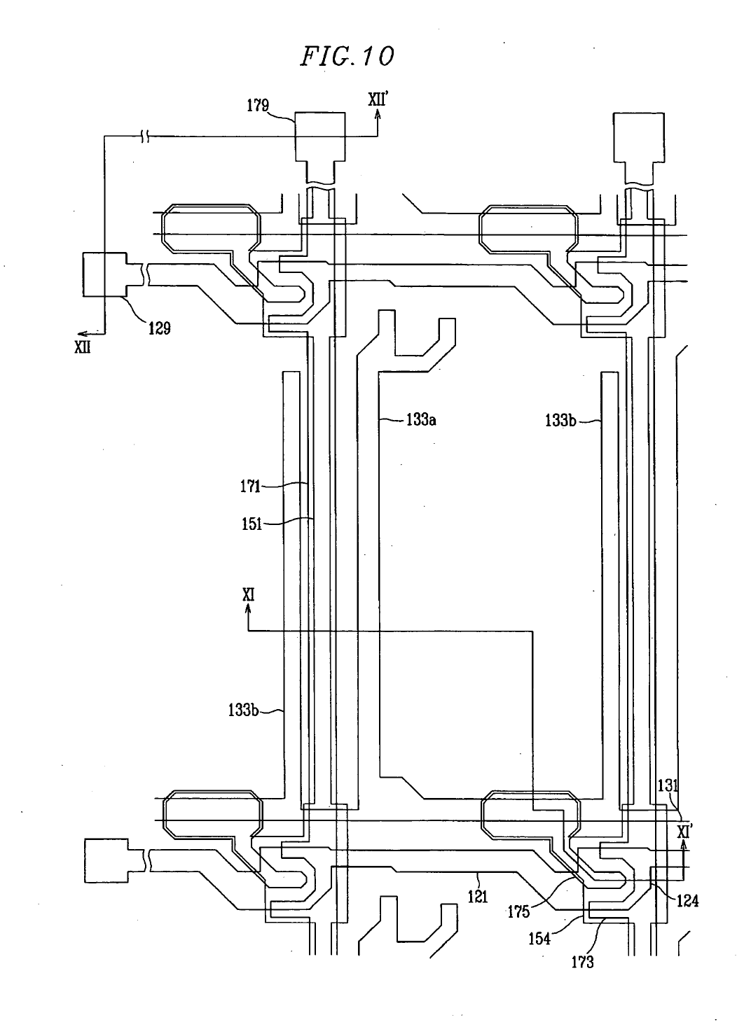

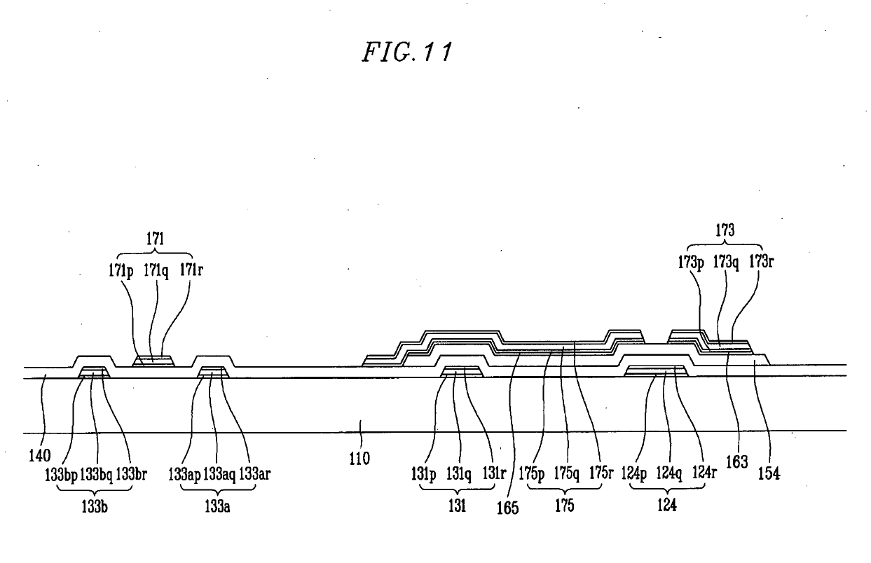

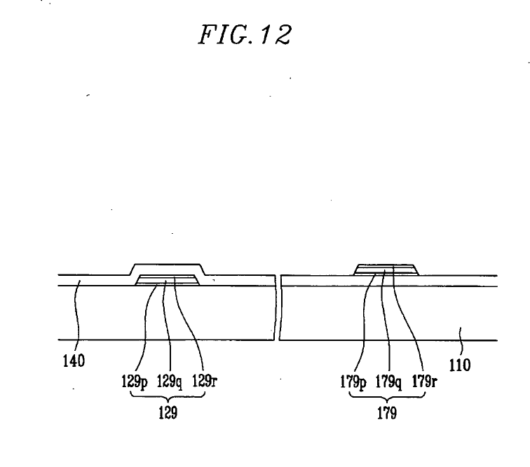

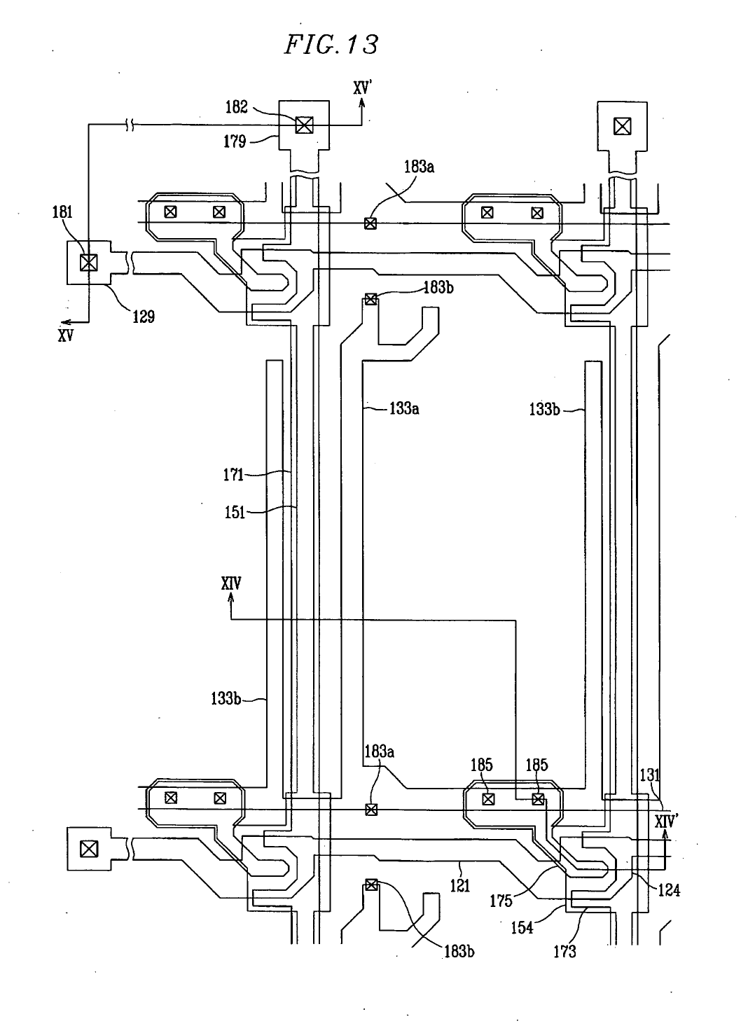

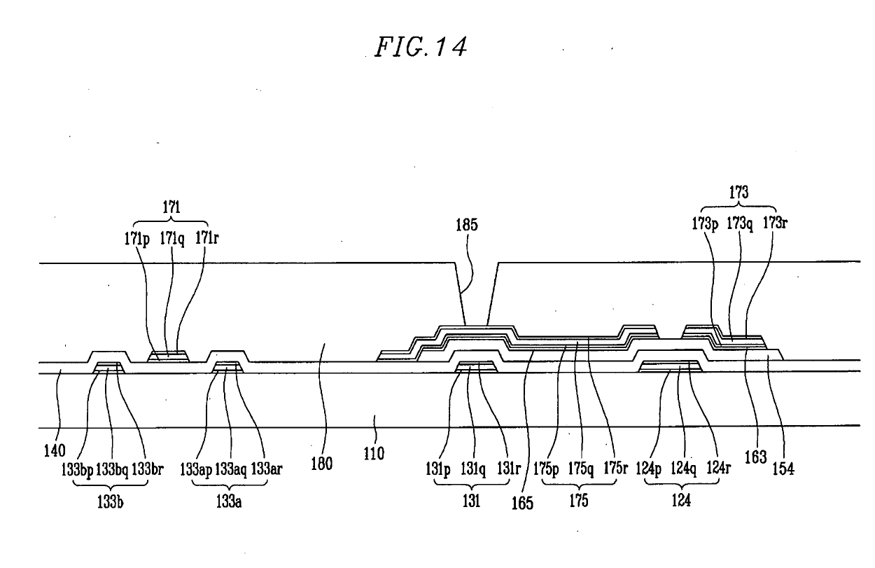

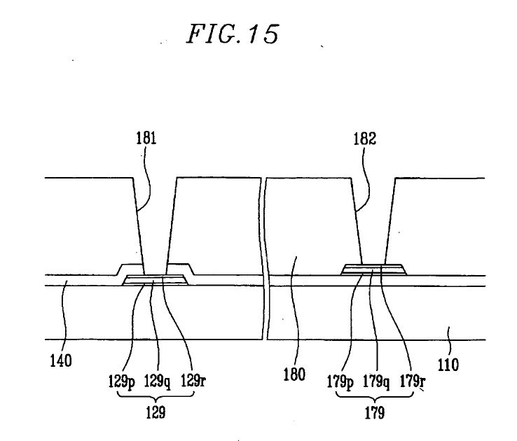

FIG. 4, FIG. 7, FIG. 10, and FIG. 13 are layout views showing process steps to manufacture a TFT array panel according to an embodiment of the present invention. FIG. 5 and FIG. 6 are schematic cross-sectional views cut along V-V′ and VI-VI′ of FIG. 4, FIG. 8 and FIG. 9 are schematic cross-sectional views cut along VIII-VII′ and IX-IX′ of FIG. 7, FIG. 11 and FIG. 12 are schematic cross-sectional views cut along XI-XI′ and XII-XII′ of FIG. 10, and FIG. 14 and FIG. 15 are schematic cross-sectional views cut along XIV-XIV′ and XV-XV′ of FIG. 13.

First, a MoNₓ layer, a Cu layer, and an ITO layer are sequentially deposited on an insulating substrate 110 made of transparent glass or plastic by sputtering, thereby forming a triple-layered stack. A more detailed description of this step is provided below.

A MoNₓ layer is first formed on the substrate 110 by supplying power only to Mo target in an N₂ ambient. The supplying of power to the MO target stops when the MoNₓ layer is completed. A Cu layer is then deposited on the MoN layer by supplying power only to the Cu target, and the supplying of power to the Cu target stops when the Cu layer is completed. An ITO layer is then deposited on the Cu layer by supplying power to the ITO target. At this time, ITO sputtering may be performed at room temperature or at a higher temperature of more than 300° C. If the sputtering is performed at below 100° C., an amorphous ITO layer may be produced, while a poly ITO layer may be produced at above 100° C. Either the amorphous ITO layer and the poly ITO layer may be used. However, in the case of the amorphous ITO layer, the amorphous ITO layer should be formed with a greater thickness than the poly ITO layer, since poly ITO is more slowly etched than amorphous ITO.

Subsequent to the formation of the triple-layered stack, as shown in FIG. 4 through FIG. 6, the MoN layer, the Cu layer, and the ITO layer are simultaneously wet etched using an etchant such as H₂O₂, thereby forming a plurality of gate lines 121 with gate electrodes 124 and end portions 129, and a plurality of storage electrode lines 131 with storage electrodes 133a and 133b. If some unnecessary protrusions are produced at edges of the ITO layer during the wet etching process due to a relatively low etching rate of the ITO layer, dry etching may be used after the wet etching to remove the protrusions from the ITO layer.

Subsequently, SiNₓ is deposited on the gate lines 121 and the storage electrode lines 131 to form a gate insulating layer 140 as shown in FIG. 7 through FIG. 9.

Subsequent to the formation of the gate insulating layer 140, an intrinsic amorphous silicon layer and a doped amorphous silicon layer are successively deposited on the gate insulating layer 140.

Then, the intrinsic amorphous silicon layer and the doped amorphous silicon layer are selectively etched by photolithography to form a plurality of linear intrinsic semiconductors 151 with a plurality of projections 154, and a plurality of doped amorphous silicon layers 161 with a plurality of impurity semiconductors 164, as shown in FIG. 7 through FIG. 9.

Subsequently, a MoNₓ layer, a Cu layer, and an ITO layer are sequentially deposited on the doped amorphous silicon layers 161 and the gate insulating layer 140 using a sputtering technique.

Next, as shown in FIG. 10 through FIG. 12, the MoN layer, the Cu layer, and the ITO layer are simultaneously wet-etched using an etchant such as H₂O₂, thereby forming a plurality of data lines 171 with source electrodes 173 and end portions 179, and a plurality of drain electrodes 175. If some unnecessary protrusions are produced at edges of the ITO layer during the wet etching process due to a relatively low etching ratio of the ITO layer, dry etching may be additionally performed after the wet etching to remove the protrusions from the ITO layer.

Next, the exposed portions of the impurity semiconductors 164, which are not covered with the source electrodes 173 and the drain electrodes 175, are removed. As a result, as shown in FIG. 10 through 12, a plurality of linear ohmic contacts 161 with projections 163, and a plurality of island-shaped ohmic contacts 165 are completed, partially exposing the underlying linear semiconductors 151. Subsequently, an O₂ plasma process is performed to stabilize the exposed surfaces of the linear semiconductors 151.

Next, as shown in FIG. 13 through 15, a passivation layer 180 is formed by depositing a photosensitive organic material with a good planarization property, such as SiNₓ, on the entire substrate 110 by plasma enhanced chemical vapor deposition (PECVD).

Subsequently, the passivation layer 180 is selectively etched by photolithography to form a plurality of contact holes 181, 182, 183a, 183b, and 185.

Subsequent to the formation of the contact holes 181, 182, 183a, 183b, and 185, a transparent conductive material, such as ITO or IZO, is deposited on the passivation layer 180 by sputtering. The deposited layer is then patterned using a mask, as shown in FIG. 7, thereby forming a plurality of pixel electrodes 191, a plurality of contact assistants 81 and 82, and a plurality of overpasses 83, as shown in FIG. 1 through FIG. 3.

In this embodiment, all of the gate lines 121 and the data lines 171 adopt a technique of the triple-layered structure, in which Mo, Cu, and a conductive oxide are deposited in sequence. This technique may be applicable to either of the two types of lines.

The above-mentioned triple-layered technique, which is applied to the wiring, improves the adhesion structure between the wiring and the underlying substrate and between the wiring and overlying layers, maintaining low resistivity characteristic of Cu in the wiring. In addition, even though the wiring is configured as triple-layered structures, the wiring can achieve good etching profiles through a single etching process by suitably controlling the etching ratios of three layers. Further, the Mo layer and the conductive oxide layer prevent Cu from diffusing into the semiconductor layers by Cu oxidation, so that characteristics of the TFTs are improved.

The present invention should not be considered limited to the particular examples described above, but rather should be understood to cover all aspects of the invention as fairly set out in the attached claims. Various modifications, equivalent processes, as well as numerous structures to which the present invention may be applicable will be readily apparent to those of skill in the art to which the present invention is directed upon review of the instant specification.

What is claimed is:

1. Wiring for a display device, comprising:
a first conductive layer comprising molybdenum (Mo);
a second conductive layer formed on the first conductive layer and comprising copper (Cu); and
a third conductive layer formed on the second conductive layer and comprising a conductive oxide.

2. The wiring of claim 1, wherein the first conductive layer comprises Mo or a Mo alloy containing Mo and at least one among niobium (Nb), tantalum (Ta), titanium (Ti), zirconium (Zr), tungsten (W), and nitride (N).

3. The wiring of claim 1, wherein the second conductive layer comprises Cu or a Cu alloy.

4. The wiring of claim 1, wherein the third conductive layer comprises at least one or more among indium tin oxide (ITO), indium zinc oxide (IZO), aluminum zinc oxide (AZO), and indium tin zinc oxide (InSnZnO).

5. A thin film transistor array panel comprising:
a substrate;
a first signal line on the substrate;
a second signal line on the substrate, the second signal line crossing the first signal line;
a thin film transistor coupled to the first signal line and the second signal line; and
a pixel electrode coupled to the thin film transistor,
wherein at least one of the two signal lines comprises:
a first conductive layer comprising molybdenum (Mo);
a second conductive layer formed on the first conductive layer and comprising copper (Cu); and
a third conductive layer formed on the second conductive layer and comprising a conductive oxide.

6. The thin film transistor array panel of claim 5, wherein the first conductive layer comprises Mo or a Mo alloy that contains Mo and at least one among Nb, Ta, Ti, Zr, W, and N.

7. The thin film transistor array panel of claim 5, wherein the second conductive layer comprises Cu or a Cu alloy.

8. The thin film transistor array panel of claim 5, wherein the third conductive layer comprises at least one or more among ITO, IZO, AZO, and InSnZnO.

9. The thin film transistor array panel of claim 5, wherein the third conductive layer comprises at least one or more among ITON, IZON, AZON, and InSnZnON.

10. The thin film transistor array panel of claim 5, wherein the second conductive layer is thicker than the first conductive layer and the third conductive layer.

11. A method of manufacturing a thin film transistor array panel comprising the steps of:
(a) forming a first signal line;
(b) forming a gate insulating layer and a semiconductor layer on the first signal line;
(c) forming a second signal line and a drain electrode on the gate insulating layer and the semiconductor layer; and
(d) forming a pixel electrode coupled to the drain electrode,
wherein at least one of the formation steps (a) and (c) of the first signal line and the second signal line includes the sub-steps of:
forming a first conductive layer comprising molybdenum (Mo),
forming a second conductive layer comprising copper (Cu), and
forming a third conductive layer comprising a conductive oxide.

12. The method of claim 11, further comprising a step of wet-etching the first, second, and third conductive layers after the formation step of the third conductive layer.

13. The method of claim 12, wherein the wet-etching step is performed using an etchant comprising hydrogen peroxide (H₂O₂).

14. The method of claim 12, further comprising a step of dry-etching the first, second, and third conductive layers after the wet-etching step.

15. The method of claim 11, wherein at least one of the formation steps of the first conductive layer and the second conductive layer is performed in an N₂ ambient.
